(19) United States
(12) Patent Application Publication
(10) Pub. No.: US 2021/0336177 A1
(43) Pub. Date: Oct. 28, 2021

(54) OLED DISPLAY PANEL AND OLED DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventors: Ting Shi, Shenzhen (CN); Shipan Wang, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/622,353

(22) PCT Filed: Nov. 18, 2019
(86) PCT No.: PCT/CN2019/119101

§ 371 Date: Dec. 13, 2019

(30) Foreign Application Priority Data
Nov. 8, 2019 (CN) 201911087930.4

(51) Int. Cl. H01L 51/50

(52) U.S. Cl. CPC H01L 51/5092; H01L 51/5056; H01L 51/5072

(57) ABSTRACT

An OLED display panel and an OLED display device are disclosed. The OLED display panel enhances electron transport efficiency by providing an interface layer between a light-emitting layer and a common electrode layer, thereby increasing the electron transport efficiency. The effect of injection of electrons into the light-emitting layer is improved, so that the light-emitting layer has an improved light-emitting effect to enhance display effect and to solve the technical problem of poor display effect of the current OLED display panel resulting from the poor effect of injection of electrons into the light-emitting layer.

### FIELD OF INVENTION

The present disclosure relates to the technical field of displays, and in particular, to an organic light-emitting diode (OLED) display panel and an OLED display device.

### BACKGROUND OF DISCLOSURE

Organic light-emitting diodes (OLEDs) are widely used in the display field due to advantages of high brightness, self-luminance, fast response times, and low driving voltages. Red, green and blue organic light-emitting diodes in the OLED display panel are arranged side by side as a light-emitting layer, and electron transport material is disposed on the light-emitting layer. The electron transport material transports electrons, thereby causing the light-emitting layer to emit light. However, since energy levels and properties of the materials of the red, green and blue light-emitting diodes are different, when electron transport materials are selected, it is necessary to comprehensively consider the performances of the three light-emitting diodes for improving the contact between the electron transport layer and the light-emitting layer and the cathode. However, in such a process, the effect of injection of electrons into the light-emitting layer is poor, thereby affecting the display effect.

Accordingly, the current OLED display panel has a poor effect of injection of electrons into the light-emitting layer, resulting in a technical problem of poor display effect.

### SUMMARY OF INVENTION

### Technical Problems

The present application provides an organic light-emitting diode (OLED) display panel and an OLED display device for solving the technical problem that the current OLED display panel has poor effect of injection of electrons into the light-emitting layer, resulting in poor display effect.

### Technical Solutions

In order to solve the aforementioned problems, a technical solution provided by the present disclosure is as follows:

The present disclosure provides an OLED display panel, comprising:

a substrate;

a driving circuit layer disposed on one side of the substrate; and

a light-emitting functional layer disposed on one side of the driving circuit layer away from the substrate, and sequentially provided with a pixel electrode layer, a hole injection layer, a hole transport layer, a light-emitting layer, an electron transporting layer, and a common electrode layer in a direction away from the substrate;

wherein at least one interface layer is disposed between the light-emitting layer and the common electrode layer, and the interface layer is configured to enhance electron transport efficiency.

In the OLED display panel provided by the present application, the interface layer is disposed between the electron transporting layer and the light-emitting layer.

In the OLED display panel provided by the present application, the interface layer is disposed between the electron transporting layer and the common electrode layer.

In the OLED display panel provided by the present application, the interface layer includes a first interface layer and a second interface layer, the first interface layer is disposed between the light-emitting layer and the electron transporting layer, and the second interface layer is disposed between the electron transporting layer and the common electrode layer.

In the OLED display panel provided by the present application, the first interface layer is a single layer structure.

In the OLED display panel provided by the present application, material of the first interface layer is the same as material of the second interface layer.

In the OLED display panel provided by the present application, the material of the first interface layer includes lithium fluoride.

In the OLED display panel provided by the present application, the material of the first interface layer is different from the material of the second interface layer.

In the OLED display panel provided by the present application, the material of the first interface layer includes metal, or organic compound doped with metal or inorganic dopant.

In the OLED display panel provided by the present application, the first interface layer includes a stacked structure of at least two different single layers.

In the OLED display panel provided by the present application, the first interface layer includes a first single layer and a second single layer, and material of the first single layer includes inorganic compound, and material of the second single layer includes metal.

In the OLED display panel provided by the present application, the material of the first single layer includes one of lithium fluoride and sodium fluoride.

In the OLED display panel provided by the present application, the material of the second single layer includes one of barium, lithium, and ytterbium.

In the OLED display panel provided by the present application, the material of the second interface layer includes lithium fluoride.

The present application further provides an OLED display device which comprises an OLED display panel, and the OLED display panel includes:

a substrate

a driving circuit layer disposed on one side of the substrate; and

a light-emitting functional layer disposed on one side of the driving circuit layer away from the substrate, and sequentially provided with a pixel electrode layer, a hole injection layer, a hole transport layer, a light-emitting layer, an electron transporting layer, and a common electrode layer in a direction away from the substrate;

wherein, at least one interface layer is disposed between the light-emitting layer and the light-emitting functional layer, and the interface layer is configured to enhance electron transport efficiency.

In the OLED display device provided by the present application, the interface layer is disposed between the electron transporting layer and the light-emitting layer.

In the OLED display device provided by the present application, the interface layer is disposed between the electron transporting layer and the common electrode layer.

In the OLED display device provided by the present application, the interface layer includes a first interface layer and a second interface layer, the first interface layer is disposed between the light-emitting layer and the electron transporting layer, and the second interface layer is disposed between the electron transporting layer and the common electrode layer.

In the OLED display device provided by the present application, the first interface layer is a single layer structure.

In the OLED display device provided by the present application, material of the first interface layer includes metal, or organic compound doped with metal or inorganic dopant.

### Beneficial Effects

The present application provides an OLED display panel and an OLED display device, and the OLED display panel includes a substrate, a driving circuit layer, and a light-emitting functional layer. The driving circuit layer is disposed on one side of the substrate, the light-emitting functional layer is disposed on one side of the driving circuit layer away from the substrate, and sequentially provided with a pixel electrode layer, a hole injection layer, a hole transport layer, a light-emitting layer, an electron transporting layer, and a common electrode layer in a direction away from the substrate. At least one interface layer is disposed between the light-emitting layer and the light-emitting functional layer, and the interface layer is configured to enhance electron transport efficiency. By providing the interface layer between the light-emitting layer and the common electrode layer, the interface layer enhances the efficiency of electron transport, thereby increasing the electron transport efficiency when electrons are transported from the common electrode layer to the light-emitting layer. The effect of injection of electrons into the light-emitting layer is improved, so that the light-emitting layer has an improved light-emitting effect to enhance display effect and to solve the technical problem of the poor display effect of the current OLED display panel resulting from the poor effect of injection of electrons into the light-emitting layer.

### BRIEF DESCRIPTION OF THE DRAWINGS

To describe the technical solutions of the embodiments or the prior art more clearly, the following outlines briefly the accompanying drawings for describing the embodiments of the present disclosure or the prior art. Apparently, the accompanying drawings described below are merely about some embodiments of the present disclosure, and persons of ordinary skill in the art can derive other drawings from the accompanying drawings without any creative effort.

FIG. 1 is the first schematic view of the OLED display panel provided by the embodiment of the present application.

FIG. 2 is the second schematic view of the OLED display panel provided by the embodiment of the present application.

FIG. 3 is a flowchart of the manufacturing method of the OLED display panel provided by the embodiment of the present application.

### DETAILED DESCRIPTION OF EMBODIMENTS

The following embodiments are referring to the accompanying drawings for exemplifying specific implementable embodiments of the present disclosure. Furthermore, directional terms described by the present disclosure, such as “upper”, “lower”, “front”, “back”, “left”, “right”, “inner”, “outer”, “side” and etc., are only directions by referring to the accompanying drawings, and thus the used directional terms are used to describe and understand the present disclosure, but the present disclosure is not limited thereto. In the drawings, structure-like elements are labeled with like reference numerals.

The present application is directed to the problem that the current organic light-emitting diode (OLED) display panel has a poor effect of injection of electrons into a light-emitting layer, resulting in a poor display effect. The embodiments of the present application are used to solve the problem.

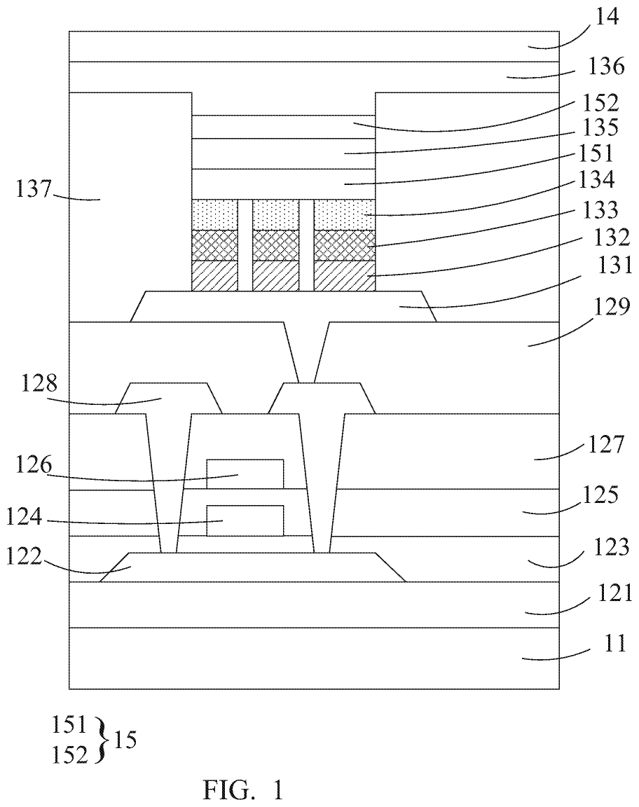

As shown in FIG. 1, an embodiment of the present application provides an OLED display panel, where the OLED display panel includes:

a substrate 11;

a driving circuit layer disposed on one side of the substrate 11; and

a light-emitting functional layer disposed on one side of the driving circuit layer away from the substrate 11, and sequentially provided with a pixel electrode layer 131, a hole injection layer 132, a hole transport layer 133, a light-emitting layer 134, an electron transporting layer 135, and a common electrode layer 136 in a direction away from the substrate 11;

wherein at least one interface layer 15 is disposed between the light-emitting layer 134 and the common electrode layer 136, and the interface layer 15 is configured to enhance electron transport efficiency.

The embodiment of the present application provides an OLED display panel which includes a substrate, a driving circuit layer, and a light-emitting functional layer. The driving circuit layer is disposed on one side of the substrate, the light-emitting functional layer is disposed on one side of the driving circuit layer away from the substrate, and sequentially provided with a pixel electrode layer, a hole injection layer, a hole transport layer, a light-emitting layer, an electron transporting layer, and a common electrode layer in a direction away from the substrate. At least one interface layer is disposed between the light-emitting layer and the light-emitting functional layer, and the interface layer is configured to enhance electron transport efficiency. By providing the interface layer between the light-emitting layer and the common electrode layer, the interface layer enhances the efficiency of electron transport, thereby increasing the electron transport efficiency when electrons are transported from the common electrode layer to the light-emitting layer. The effect of injection of electrons into the light-emitting layer is improved, so that the light-emitting layer has an improved light-emitting effect to enhance display effect and to solve the technical problem of the poor display effect of the current OLED display panel resulting from the poor effect of injection of electrons into the light-emitting layer.

In one embodiment, the driving circuit layer includes a buffer layer 121, an active layer 122, a first gate insulating layer 123, a first metal layer 124, a second gate insulating layer 125, a second metal layer 126, an interlayer insulating layer 127, a source/drain layer 128, and a planarization layer 129. The driving circuit layer which is formed with a driving circuit is connected to the pixel electrode layer. The driving circuit drives the pixel electrode to control the light-emitting layer to emit light.

In one embodiment, the liquid crystal display panel further includes a pixel define layer 137 disposed on the pixel electrode layer 131. The pixel define layer defines a light-emitting region.

In one embodiment, the OLED display panel further includes an encapsulation layer 14 including an inorganic layer and an organic layer disposed in a stacked manner.

In one embodiment, the interface layer is disposed between the electron transporting layer and the light-emitting layer. That is, by providing an interface layer between the electron transporting layer and the light-emitting layer, the contact between the electron transporting layer and the light-emitting layer is improved, thereby increasing the effect of injection of electrons from the electron transporting layer into the light-emitting layer. Accordingly, the effect of injection of electrons into the light-emitting layer is improved.

In one embodiment, the interface layer is disposed between the electron transporting layer and the common electrode layer. By providing an interface layer between the electron transporting layer and the common electrode layer, the contact between the electron transporting layer and the common electrode layer is improved, so that the transport of the electrons between the common electrode layer and the electron transporting layer is improved to enhance the effect of injection of electrons into the light-emitting layer, thereby improving the display effect.

In one embodiment, as shown in FIG. 1, the interface layer 15 includes a first interface layer 151 and a second interface layer 152. The first interface layer 151 is disposed between the light-emitting layer 134 and the electron transporting layer 135. The second interface layer 152 is disposed between the electron transporting layer 135 and the common electrode layer 136. By providing the first interface layer between the light-emitting layer and the electron transporting layer and providing the second interface layer between the electron transporting layer and the common electrode layer, both the contact between the light-emitting layer and the electron transporting layer and the contact between the electron transporting layer and the common electrode layer are improved, so that the electron transport effect between the contacted film layers is enhanced in the process of electron transport from the common electrode layer to the electron transporting layer and then to the light-emitting layer, thereby enhancing the effect of injection of electrons into the light-emitting layer. Moreover, material of the first interface layer may be different from that of the second interface layer. When the interface layer is disposed, the material of the first interface layer is selected according to performance of the light-emitting layer and the electron transporting layer and demand of contact between the light-emitting layer and the electron transporting layer. That is, the material of the first interface layer is determined according to the light-emitting layer and the electron transporting layer. The first interface layer greatly increases the effect of injection of electrons from the electron transporting layer into the light-emitting layer. Similarly, the material of the second interface layer may be selected according to performance of the electron transporting layer and the common electrode layer and demand of contact between the electron transporting layer and the common electrode layer. That is, the material of the second interface layer is determined according to the electron transporting layer and the common electrode layer. The second interlace layer greatly increases the effect of electron transport between the common electrode layer and the electron transporting layer. The material selections of the first interface layer and the second interface layer, and the thickness selections of the first interface layer and the second interface layer are all selected according to the respective connected film layers, so that the effect of electron transport between the respective layers in the process of electron transport from the common electrode layer to the light-emitting layer is improved, thereby solving the problem of the poor effect of electron transport to the light-emitting layer.

In one embodiment, the first interface layer is a single layer structure. The first interface layer with the single layer structure has a thin thickness, thereby preventing the first interface layer from increasing a thickness of the OLED display panel when the first interface layer is used to improve the effect of injection of electrons between the electron transporting layer and the light-emitting layer. Moreover, a thickness of the pixel define layer may not be increased greatly when the pixel define layer is disposed, thereby avoiding a thickness increase of the OLED display panel to reduce the cost.

In one embodiment, material of the first interface layer is the same as that of the second interface layer. When the materials of the first interface layer and the second interface layer are selected, the materials which can improve the effect of electron transport between the respective film layers are necessary to be selected. Moreover, the material of the first interface layer may be the same as that of the second interface layer, so that only one material needs to be determined when the materials of the first interface layer and the second interface layer are selected. Accordingly, the first interface layer and the second interface layer which are manufactured by the same material can enhance the electron transport effect.

In one embodiment, the material of the first interface layer includes inorganic material. The material of the first interface layer comprises lithium fluoride. When the materials of the first interface layer and the second interface layer are selected, lithium fluoride may be selected, so that the first interface layer enhances the effect of the electron transport from the electron transporting layer to the light-emitting layer, and the second interface layer enhances the effect of the electron transport from the common electrode layer to the electron transporting layer.

In one embodiment, the first interface layer has a thickness of less than 20 nm.

In one embodiment, material of the first interface layer is different from that of the second interface layer. The materials of the first interface layer and the second interface layer may be considered based on performance of the common electrode layer and the electron transporting layer, and performance of the electron transporting layer and the light-emitting layer, so that the material of the first interface layer and the material of the second interface layer may be selected separately. Accordingly, the material of the first interface layer achieves the effect of improving the electron transport from the electron transporting layer to the light-emitting layer, and the material of the second interface layer achieves the effect of improving the electron transport from the common electrode layer to the electron transporting layer.

In one embodiment, the material of the first interface layer includes metal, organic compound doped with metal, or inorganic dopant. When the material of the first interface layer is selected, metal material, such as barium, lithium, and ytterbium, may be selected as the material of the first interface layer. The organic compound doped with metal, such as organic dopant or lithium, may also be selected as the material of the first interface layer. The inorganic dopant, such as sodium fluoride or lithium fluoride, may further be selected as the material of the first interface layer.

In one embodiment, the first interface layer includes a stacked structure of at least two different single layer members. With the stacked structure of the first interface layer, a single layer in the first interface layer that is in contact with the electron transporting layer has an improved effect of receiving electrons from the electron transporting layer when the electrons from the first interface layer are transported from the electron transporting layer to the light-emitting layer. A single layer in the second interface layer that is in contact with the light-emitting layer has an improved effect of electron transport to the light-emitting layer. The electron transport effect reaches an improved state in the process of electron transport from the electron transporting layer to the light-emitting layer with the improved effect of electron transport between the two single layers.

In one embodiment, the first interface layer includes a first single layer and a second single layer. Material of the first single layer includes inorganic compound, and material of the second single layer includes metal. When materials of the first single layer and the second single layer are selected, inorganic compound, such as sodium fluoride, may be selected as the material of the first single layer, and metal, such as barium, may be selected as the material of the second single layer.

In one embodiment, the material of the first single layer includes one of lithium fluoride and sodium fluoride.

In one embodiment, the material of the second single layer includes one of barium, lithium, and ytterbium.

In one embodiment, the second single layer has a thickness of less than 5 nm.

In one embodiment, the material of the second interface layer includes lithium fluoride.

In one embodiment, the second interface layer has a thickness of less than 5 nm.

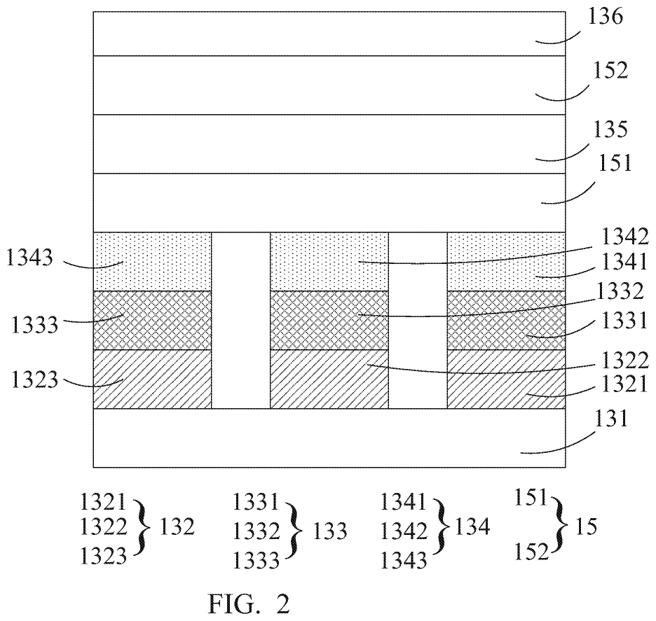

In one embodiment, as shown in FIG. 2, the hole injection layer 132 includes a first hole injection unit 1321, a second hole injection unit 1322, and a third hole injection unit 1323. The hole transport layer 133 includes a first hole transport unit 1331, a second hole transport unit 1332, and a third hole transport unit 1333. The light-emitting layer includes a first light-emitting unit 1341, a second light-emitting unit 1342, and a third light-emitting unit 1343. When the light-emitting layer is disposed, the first light-emitting unit, the second light-emitting unit, and the third light-emitting unit are spaced apart, such that crosstalk may not occur among the first light-emitting unit, the second light-emitting unit, and the third light-emitting unit. When the hole injection layer and the hole transport layer are correspondingly disposed, the first hole injection unit and the first hole transport unit are correspondingly disposed on the first light-emitting unit, the second hole injection unit and the second hole transport layer are correspondingly disposed on the second light-emitting unit, and the third hole injection unit and the third hole injection unit are correspondingly disposed on the third light-emitting unit, so that crosstalk may not occur among the first light-emitting unit, the second light-emitting unit, and the third light-emitting unit.

In one embodiment, the first light-emitting unit includes a blue light-emitting unit, a green light-emitting unit, and a red light-emitting unit. The second light-emitting unit includes a blue light-emitting unit, a green light-emitting unit, and a red light-emitting unit. The third light-emitting unit includes a blue light-emitting unit, a green light-emitting unit, and a red light-emitting unit. The colors of the first light-emitting unit, the second light-emitting unit, and the third light-emitting unit are different.

In one embodiment, the first light-emitting unit is a blue light-emitting unit, the second light-emitting unit is a green light-emitting unit, and the third light-emitting unit is a red light-emitting unit.

In one embodiment, materials of the first hole injection unit, the second hole injection unit, and the third hole injection unit are the same. When holes are injected into the light-emitting layer, the materials of the first hole injection unit, the second hole injection unit and the third hole injection unit respectively corresponding to the first light-emitting unit, the second light-emitting unit and the third light-emitting unit are the same. When the hole injection layer is disposed, the same material is used to form the first hole injection unit, the second hole injection unit, and the third hole injection unit respectively at the corresponding positions to obtain the hole injection layer.

In one embodiment, the materials of the first hole injection unit, the second hole injection unit, and the third hole injection unit are different. Different hole injection units may be used for three different light-emitting units. Thus, the hole injection unit meets the requirements of the light-emitting unit to improve the light-emitting effect.

In one embodiment, the materials of the first hole transport unit, the second hole transport unit, and the third hole transport unit are the same. When holes are transported to the light-emitting layer, the materials of the first hole transport unit, the second hole transport unit, and the third hole transport unit corresponding to the first light-emitting unit, the second light-emitting unit and the third light-emitting unit may be the same. When the hole transport layer is disposed, the same material is used to form the first hole transport unit, the second hole transport unit, and the third hole transport unit respectively at the corresponding positions to obtain the hole transport layer.

In one embodiment, the materials of the first hole transport unit, the second hole transport unit, and the third hole transport unit are different. Different hole transport units may be used for three different light-emitting units. Thus, the hole transport unit meets the requirements of the light-emitting unit to improve the light-emitting effect.

In one embodiment, the first interface layer is disposed to be an entire surface. The materials of each part of the first interface layer are the same.

In one embodiment, each portion of the first interface layer is disposed on an interval. The first interface layer includes a first portion corresponding to the first light-emitting unit, a second portion corresponding to the second light-emitting unit, and a third portion corresponding to the third light-emitting unit. Each portion of the first interface layer corresponds to the light-emitting units respectively. Material of each portion of the first interface layer is different from each other. When the first interface layer is disposed to correspond to the different light-emitting units, the material of each portion of the first interface layer may be different from each other, thereby improving the effect of electron transport from the electron transporting layer to the light-emitting layer according to requirements of the material of the first interface layer. When the material of the first interface layer is selected, the material of the first interface layer may be selected according to requirements, such as improved effect, cost, and degree of cooperation with the corresponding light-emitting unit.

In one embodiment, the second interface layer is disposed to be an entire surface. The materials of each part of the second interface layer are the same.

In one embodiment, each portion of the second interface layer is disposed on an interval. The second interface layer includes a first portion corresponding to the first light-emitting unit, a second portion corresponding to the second light-emitting unit, and a third portion corresponding to the third light-emitting unit. Each portion of the second interface layer corresponds to the light-emitting units respectively. Material of each portion of the second interface layer is different from each other. The second interface layer may also be provided with a separation disposition, so that each portion of the second interface layer is selected according to requirements to improve electronic transport while the cost is reduced.

In one embodiment, the pixel electrode layer is a stack of layers of silver and indium tin oxide, and the silver is disposed under the indium tin oxide. A thickness of the silver is selected to be 140 nm, and a thickness of the indium tin oxide is selected to be 15 nm. Then, the hole injection layer is disposed on the pixel electrode layer. A thickness of the hole injection layer is selected to be 20 nm. The hole transport layer is formed on the hole injection layer. A thickness of the hole transport layer is selected to be 20 nm. Then, a blue light-emitting unit is formed on the hole transport layer. A thickness of the blue light-emitting unit is selected to be 50 nm. Then, a first interface layer is formed on the blue light-emitting unit. The first interface layer is a stack of layers, where a first single layer is sodium fluoride and a second single layer is barium. A thickness of the first single layer is selected to be 3 nm, and a thickness of the second single layer is selected to be 10 nm. Then, the electron transporting layer is formed on the first interface layer. A thickness of the electron transporting layer is selected to be 110 nm. Then, a second interface layer is formed on the electron transporting layer. Material of the second interface layer is lithium fluoride. A thickness of the second interface layer is selected to be 1 nm. Then, a common electrode layer is formed on the second interface layer. Material of the common electrode layer is selected from silver, and a thickness of the common electrode layer is selected to be 18 nm. A parameter comparison table of the blue light-emitting unit of the OLED display panel with or without the second interface layer is as shown in table 1:

TABLE 1

| | | | Voltage | J | CE | |
|---|---|---|---|---|---|---|
| | CIEx | CIEy | (V) | (mA/cm²) | (cd/A) | CE/CIEy |
| with the | 0.140 | 0.068 | 5.75 | 24.86 | 3.65 | 53.31 |
| second | | | | | | |
| interface | | | | | | |
| layer | | | | | | |
| without | 0.140 | 0.066 | 7.25 | 29.61 | 3.37 | 51.19 |
| the | | | | | | |
| second | | | | | | |
| interface | | | | | | |
| layer | | | | | | |

In the table 1, CIEx and CIEy represent color coordinates (x, y). Voltage represents voltage, and the unit is V, i.e., volt. J represents current density, and the unit is mA/cm², i.e., milliampere/square centimeter. CE represents photometric efficiency, and the unit is cd/A, i.e., candela/ampere. CE/CIEy represents chromaticity efficiency, and a high chromaticity efficiency represents a high display effect of the blue light-emitting unit. As can be seen from table 1, after the second interface layer is employed, the voltage corresponding to the blue light-emitting unit decreases while the chromaticity efficiency is improved. That is, the voltage is lowered, so that the possibility of damage of the blue light-emitting unit is reduced, and the life span of the blue light-emitting unit is improved to improve the display effect of the blue light-emitting unit.

The embodiment of the present application provides an OLED display device which includes an OLED display panel, and the OLED display panel includes:

a substrate;

a driving circuit layer disposed on one side of the substrate; and

a light-emitting functional layer disposed on one side of the driving circuit layer away from the substrate, and sequentially provided with a pixel electrode layer, a hole injection layer, a hole transport layer, a light-emitting layer, an electron transporting layer, and a common electrode layer in a direction away from the substrate;

wherein, at least one interface layer is disposed between the light-emitting layer and the light-emitting functional layer, and the interface layer is configured to enhance electron transport efficiency.

The embodiment of the present application provides an OLED display device which includes an OLED display panel, and the OLED display panel includes a substrate, a driving circuit layer, and a light-emitting functional layer. The driving circuit layer is disposed on one side of the substrate, the light-emitting functional layer is disposed on one side of the driving circuit layer away from the substrate, and sequentially provided with a pixel electrode layer, a hole injection layer, a hole transport layer, a light-emitting layer, an electron transporting layer, and a common electrode layer in a direction away from the substrate. At least one interface layer is disposed between the light-emitting layer and the light-emitting functional layer, and the interface layer is configured to enhance electron transport efficiency. By providing the interface layer between the light-emitting layer and the common electrode layer, the interface layer enhances the efficiency of electron transport, thereby increasing electron transport efficiency when electrons are transported from the common electrode layer to the light-emitting layer. The effect of injection of electrons into the light-emitting layer is improved, so that the light-emitting layer has an improved light-emitting effect to enhance display effect and to solve the technical problem of poor display effect of the current OLED display panel resulting from poor effect of injection of electrons into the light-emitting layer.

In one embodiment, the interface layer is disposed between the electron transporting layer and the light-emitting layer.

In one embodiment, the interface layer is disposed between the electron transporting layer and the common electrode layer.

In one embodiment, the interface layer includes a first interface layer and a second interface layer, the first interface layer is disposed between the light-emitting layer and the electron transporting layer, and the second interface layer is disposed between the electron transporting layer and the common electrode layer.

In one embodiment, the first interface layer is a single layer structure.

In one embodiment, material of the first interface layer includes metal, or organic compound doped with metal or inorganic dopant.

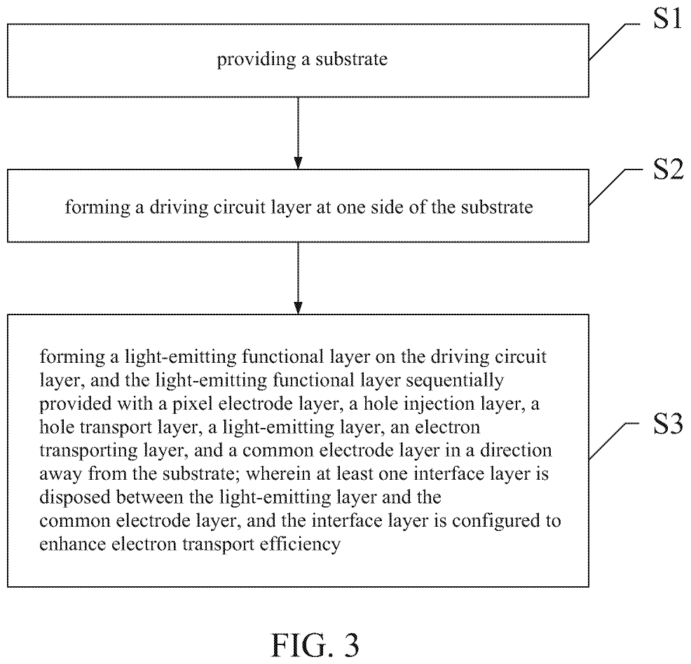

As shown in FIG. 3, the embodiment of the present application provides a manufacturing method of an OLED display panel, and the manufacturing method of the OLED display panel includes steps:

S1, providing a substrate;

S2, forming a driving circuit layer on one side of the substrate; and

S3, forming a light-emitting functional layer on the driving circuit layer, wherein the light-emitting function layer is sequentially provided with a pixel electrode layer, a hole injection layer, a hole transport layer, a light-emitting layer, an electron transporting layer, and a common electrode layer in a direction away from the substrate. At least one interface layer is disposed between the light-emitting layer and the common electrode layer, and the interface layer is used to enhance electron transport efficiency.

The embodiment of the present application provides a manufacturing method of an OLED display panel, and the OLED display panel manufactured by the manufacturing method of the OLED display panel includes a substrate, a driving circuit layer, and a light-emitting functional layer. The driving circuit layer is disposed on one side of the substrate, the light-emitting functional layer is disposed on one side of the driving circuit layer away from the substrate, and sequentially provided with a pixel electrode layer, a hole injection layer, a hole transport layer, a light-emitting layer, an electron transporting layer, and a common electrode layer in a direction away from the substrate. At least one interface layer is disposed between the light-emitting layer and the light-emitting functional layer, and the interface layer is configured to enhance electron transport efficiency. By providing the interface layer between the light-emitting layer and the common electrode layer, the interface layer enhances the efficiency of electron transport, thereby increasing the electron transport efficiency when electrons are transported from the common electrode layer to the light-emitting layer. The effect of injection of electrons into the light-emitting layer is improved, so that the light-emitting layer has an improved light-emitting effect to enhance the display effect and to solve the technical problem of the poor display effect of the current OLED display panel resulting from poor effect of injection of electrons into the light-emitting layer.

In one embodiment, the step of manufacturing the pixel electrode layer includes forming the pixel electrode layer by magnetron sputtering.

In one embodiment, the step of manufacturing the hole injection layer includes forming the hole injection layer by inkjet printing.

In one embodiment, the step of manufacturing the hole transport layer includes forming the hole transport layer by inkjet printing.

In one embodiment, the step of manufacturing the light-emitting layer includes forming the light-emitting by inkjet printing.

In one embodiment, the step of manufacturing the first interface layer includes forming the first interface layer by vacuum thermal evaporation.

In one embodiment, the step of manufacturing the electron transporting layer includes forming the electron transporting layer by vacuum thermal evaporation.

In one embodiment, the step of manufacturing the second interface layer includes forming the second interface layer by vacuum thermal evaporation.

In one embodiment, the step of manufacturing the common electrode layer includes forming the common electrode layer by vacuum thermal evaporation.

According to the above embodiment, it can be known that:

The embodiments of the present application provide an OLED display panel and an OLED display device, and the OLED display panel manufactured by the manufacturing method of the OLED display panel includes a substrate, a driving circuit layer, and a light-emitting functional layer. The driving circuit layer is disposed on one side of the substrate, the light-emitting functional layer is disposed on one side of the driving circuit layer away from the substrate, and sequentially provided with a pixel electrode layer, a hole injection layer, a hole transport layer, a light-emitting layer, an electron transporting layer, and a common electrode layer in a direction away from the substrate. At least one interface layer is disposed between the light-emitting layer and the light-emitting functional layer, and the interface layer is configured to enhance electron transport efficiency. By providing the interface layer between the light-emitting layer and the common electrode layer, the interface layer enhances the efficiency of electron transport, thereby increasing the electron transport efficiency when electrons are transported from the common electrode layer to the light-emitting layer. The effect of injection of electrons into the light-emitting layer is improved, so that the light-emitting layer has an improved light-emitting effect to enhance display effect and to solve the technical problem of the poor display effect of the current OLED display panel resulting from the poor effect of injection of electrons into the light-emitting layer.

In summary, although a few preferred embodiments of the present application have been disclosed as mentioned, the above preferred embodiments are not used for limiting the present application. Various changes and modifications may be made by those of ordinary skill in the art without departing from the spirit and scope of the present application. Thus, the protection scope of the present application is based on the scope of the appended claims.

What is claimed is:

1. An organic light-emitting diode (OLED) display panel, comprising:
a substrate;
a driving circuit layer disposed on one side of the substrate; and
a light-emitting functional layer disposed on one side of the driving circuit layer away from the substrate, and sequentially provided with a pixel electrode layer, a hole injection layer, a hole transport layer, a light-emitting layer, an electron transporting layer, and a common electrode layer in a direction away from the substrate;
wherein at least one interface layer is disposed between the light-emitting layer and the common electrode layer, and the interface layer is configured to enhance electron transport efficiency.

2. The OLED display panel of claim 1, wherein the interface layer is disposed between the electron transporting layer and the light-emitting layer.

3. The OLED display panel of claim 1, wherein the interface layer is disposed between the electron transporting layer and the common electrode layer.

4. The OLED display panel of claim 1, wherein the interface layer includes a first interface layer and a second interface layer, the first interface layer is disposed between the light-emitting layer and the electron transporting layer, and the second interface layer is disposed between the electron transporting layer and the common electrode layer.

5. The OLED display panel of claim 4, wherein the first interface layer is a single layer structure.

6. The OLED display panel of claim 5, wherein material of the first interface layer is the same as material of the second interface layer.

7. The OLED display panel of claim 6, wherein the material of the first interface layer includes lithium fluoride.

8. The OLED display panel of claim 5, wherein the material of the first interface layer is different from the material of the second interface layer.

9. The OLED display panel of claim 8, wherein the material of the first interface layer includes metal, or organic compound doped with metal or inorganic dopant.

10. The OLED display panel of claim 4, wherein the first interface layer includes a stacked structure of at least two different single layers.

11. The OLED display panel of claim 10, wherein the first interface layer includes a first single layer and a second single layer, and material of the first single layer includes inorganic compound, and material of the second single layer includes metal.

12. The OLED display panel of claim 11, wherein the material of the first single layer includes one of lithium fluoride and sodium fluoride.

13. The OLED display panel of claim 11, wherein the material of the second single layer includes one of barium, lithium, and ytterbium.

14. The OLED display panel of claim 4, wherein the material of the second interface layer includes lithium fluoride.

15. An OLED display device, comprising: an OLED display panel, and the OLED display panel includes:
a substrate
a driving circuit layer disposed on one side of the substrate; and
a light-emitting functional layer disposed on one side of the driving circuit layer away from the substrate, and sequentially provided with a pixel electrode layer, a hole injection layer, a hole transport layer, a light-emitting layer, an electron transporting layer, and a common electrode layer in a direction away from the substrate;
wherein, at least one interface layer. is disposed between the light-emitting layer and the light-emitting functional layer, and the interface layer is configured to enhance electron transport efficiency.

16. The OLED display device of claim 15, wherein the interface layer is disposed between the electron transporting layer and the light-emitting layer.

17. The OLED display device of claim 15, wherein the interface layer is disposed between the electron transporting layer and the common electrode layer.

18. The OLED display device of claim 15, wherein the interface layer includes a first interface layer and a second interface layer, the first interface layer is disposed between the light-emitting layer and the electron transporting layer, and the second interface layer is disposed between the electron transporting layer and the common electrode layer.

19. The OLED display device of claim 18, wherein the first interface layer is a single layer structure.

20. The OLED display device of claim 19, wherein material of the first interface layer includes metal, or organic compound doped with metal or inorganic dopant.
